(19) United States
(12) Patent Application Publication
(10) Pub. No.: US 2008/0217679 A1
(43) Pub. Date: Sep. 11, 2008

(54) MEMORY UNIT STRUCTURE AND OPERATION METHOD THEREOF

(75) Inventor: Chao-I Wu, Hsinchu (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 11/683,768

(22) Filed: Mar. 8, 2007

(51) Int. Cl. H01L 29/792; G11C 11/40

(52) U.S. Cl. 257/324; 365/184; 257/E29.309

(57) ABSTRACT

A memory unit is proposed. The memory unit includes a Si substrate, a trapping layer formed on the Si substrate, a first and a second doping regions formed in the Si substrate on either side of the trapping layer, a gate formed on the trapping layer, a first oxide layer formed between the gate and the trapping layer, a high-Dit material layer formed between the Si substrate and the trapping layer, and a second oxide layer formed between the high-Dit material layer and the trapping layer, wherein an interface trap density (Dit) between the high-Dit material layer and the Si substrate is in a rang from 10¹¹ cm⁻²eV⁻¹ to 10¹³ cm⁻²eV⁻¹.

### BACKGROUND OF THE INVENTION

1. Field of the Invention

The present invention relates to a memory unit structure, and in particular, to a memory unit structure that can reduce swing degradation impact after operation, and an operation method thereof.

2. Description of Related Art

In current non-volatile memory products, SONOS memory units which can perform multi-time data operations, such as recording, accessing and erasing, and perform two-bit operation in a memory unit have become one kind of memory elements utilized widely in personal computers and electronic devices.

Generally, a SONOS memory unit substitute the Poly-Si floating gate of the well known flash memory with a charge trapping layer, and there is typically a layer of silicon oxide on or under such a charge trapping layer to form a stacked structure consists of silicon oxide/silicon nitride/silicon oxide (ONO) layer. Additionally, a source and a drain are provided in the substrates on each side of the ONO layer, and a gate is provided on the ONO layer.

Because the bottom oxide layer of the ONO layer in the conventional SONOS memory unit is directly formed on the substrate through thermal oxidation, there is a low interface trap density (Dit) (about 10¹⁰ cm⁻²eV⁻¹) between the bottom oxide layer and the substrate of the silicon wafer. However, it has been found that the Dit value can gradually increase according to an increase of the cycle times of the memory unit, as shown in FIG. 1, wherein slops of either initial erase state or initial program state both differ greatly from those after ten thousand cycles. Therefore, it results in swing performance degradation, and then further affects the operation, cycle endurance and data retention of the memory unit.

### SUMMARY OF THE INVENTION

The invention provides a memory unit structure that can stabilize swing performance after cycling operations.

The invention further provides a memory unit operation method which can perform high endurance two-bit operation on a memory unit.

The invention further provides a memory unit operation method to solve the loss of start-up voltage (Vt).

The invention further provides a memory unit structure for reducing swing degradation impact after operation.

The invention yet provides a memory unit operation method which can maintain data retention of a memory unit.

The invention further provides a memory unit operation method to perform unitary bit operation and improve cycle durability of a memory unit.

The invention provides a memory unit structure comprising a Si substrate; a trapping layer formed on the Si substrate; a first and a second doping regions in the Si substrate on either side of the trapping layer, respectively; a gate formed on the trapping layer; a first oxide layer formed between the gate and the trapping layer; a high-Dit material layer formed between the Si substrate and the trapping layer, and a second oxide layer formed between the high-Dit material layer and the trapping layer; wherein an interface trap density between the high-Dit material layer and the Si substrate is in a range of 10¹¹ cm⁻²eV⁻¹ to 10¹³ cm⁻²eV⁻¹.

In one embodiment of the invention, an interface trap density between the high-Dit material layer and the Si substrate is 10¹² cm⁻²eV⁻¹.

In one embodiment of the invention, a thickness of the high-Dit material layer is in the range of 10 Å to 70 Å.

In one embodiment of the invention, a material of the high-Dit material layer comprises silicon nitride.

In one embodiment of the invention, the material of the high-Dit material layer comprises hafnium dioxide (HfO₂), zirconium dioxide (ZrO₂), zirconium oxynitride (ZrOₓN_{y}), hafnium oxynitride (HfOₓN_{y}), hafnium silicate (HfSiₓO_{y}), zirconium silicate (ZrSiₓO_{y}), hafnium silicon oxynitride (HfSiₓO_{y}N_{z}), alumina (Al₂O₃), titanium dioxide (TiO₂), tantalic oxide (Ta₂O₅), lanthanum sesquioxide (La₂O₃), cerium dioxide (CeO₂), bismuth silicate (Bi₄Si₂O₁₂), wolframium oxide (WO₃), yttrium oxide (Y₂O₃), lanthanum aluminate (LaAlO₃), barium strontium titanate (Ba₁₋ₓSrₓTiO₃), barium titanate (BaTiO₃), lead zirconate (PbZrO₃), lead scandium tantalate (PbSc_{z}Ta_{1-z}O₃, PST for short), lead zinc niobate (PbZn_{z}Nb_{1-z}O₃, PZN for short), lead zirconate titanate (PbZrO₃—PbTiO₃, PZT for short), or lead magnesium niobate (PbMg_{z}Nb_{1-z}O₃, PMN for short).

In one embodiment of this invention, the Si substrate is a p-type Si substrate, and the first and the second doping regions are n-type doping regions.

The invention further provides a memory unit operation method adapted to the aforementioned memory unit in which an interface trap density (Dit) between a high-Dit material layer and a Si substrate is in a range of 10¹¹ cm⁻²eV⁻¹ to 10¹³ cm⁻²eV⁻¹. The operation method comprises: when the memory unit is programmed, applying a first positive voltage to the gate, applying a second positive voltage to the second doping region, and setting the voltage of the first doping region at 0 Volt, so as to program bits on one side of the memory unit by means of channel hot electron (CHE); and, when the memory unit is erased, applying a first negative voltage to the gate, applying a third positive voltage to the second doping region, and setting the voltage of the first doping region at 0 Volt, so as to erase the bits on the side of the memory unit by means of band-to-band tunneling hot hole (BTBTHH).

The invention yet provides a memory unit operation method adapted to the aforementioned memory unit in which an interface trap density (Dit) between a high-Dit material layer and a Si substrate is in a range of 10¹¹ cm⁻²eV⁻¹ to 10¹³ cm⁻²eV⁻¹. The operation method comprises: when the memory unit is programmed, applying a fourth positive voltage to the gate, and setting the voltages of the first doping region and the second doping region at 0 Volt, so as to program the memory unit by means of Fowler-Nordheim (FN); and, when the memory unit is erased, applying a second negative voltage to the gate, and setting the voltages of the first doping region and the second doping region at 0 Volt, so as to erase the memory unit by means of Fowler-Nordheim (FN).

In one embodiment of the invention, the first doping region is a source, and the second doping region is a drain.

In one embodiment of the invention, the first doping region is a drain, and the second doping region is a source.

In one embodiment of the invention, the first positive voltage is higher than the second positive voltage.

The present invention further provides a memory unit which comprises a Si substrate; a trapping layer on the Si substrate; a first and a second doping regions in the Si substrate on either side of the trapping layer, respectively; a gate on the trapping layer; a first dielectric layer between the gate and the trapping layer; and a second dielectric layer between the Si substrate and the trapping layer, wherein an interface trap density (Dit) between the second dielectric layer and the Si substrate is in the range of 10¹¹ cm⁻²eV⁻¹ to 10¹³ cm⁻²eV⁻¹.

In another embodiment of the invention, an interface trap density between the second dielectric layer and the Si substrate is 10¹² cm⁻²eV⁻¹.

In another embodiment of the invention, the second dielectric layer comprises an oxide layer.

In another embodiment of the invention, the Si substrate is a p-type Si substrate, and the first and the second doping regions are n-type doping regions.

In another embodiment of the invention, the first dielectric layer comprises an oxide layer.

The invention further provides a memory unit operation method adapted to the aforementioned memory in which an interface trap density (Dit) between a second dielectric layer and a Si substrate is in a range of 10¹¹ to 10¹³ cm⁻²eV⁻¹. The operation method comprises: when the memory unit is programmed, applying a first positive voltage to the gate, applying a second positive voltage on the second doping region, and setting the voltage of the first doping region at 0 Volt, so as to program bits on one side of the memory unit by means of channel hot electron (CHE); when the memory unit is erased, applying a first negative voltage to the gate, applying a third positive voltage to the second doping region, and setting the voltage of the first doping region at 0 Volt, so as to erase the bits on the side of the memory unit by means of band-to-band tunneling hot hole (BTBTHH).

The invention still provides a memory unit operation method adapted to the aforementioned memory unit in which an interface trap density (Dit) between a second dielectric layer and a Si substrate is in a range of 10¹¹ to 10¹³ cm⁻²eV⁻¹. The operation method comprises: when the memory unit is programmed, applying a fourth positive voltage to the gate, and setting the voltages of the first and the second doping regions at 0 Volt, so as to program the memory unit by means of Fowler-Nordheim (FN); when the memory unit is erased, applying a second negative voltage to the gate, and setting the voltages of the first and the second doping regions at 0 Volt, so as to erase the memory unit by means of Fowler-Nordheim (FN).

In another embodiment of the invention, the first doping region is a source, and the second doping region is a drain.

In another embodiment of the invention, the first doping region is a drain, and the second doping region is a source.

In another embodiment of the invention, the first positive voltage is higher than the second positive voltage.

Since the interface between the Si substrate and its upper layer has a high interface trap density (Dit) in the range of 10¹¹ cm⁻²eV⁻¹ to 10¹³ cm⁻²eV⁻¹ in the present invention, its swing performance can be maintained to a degree as the cycle times gradually increase. Therefore, the operation, cycle endurance, and data retention of the memory unit can be maintained within a permissible range as possible, and keep the memory unit available.

These feathers and advantages of the invention can become more apparent from following preferred embodiments, in conjunction with appended drawings.

### BRIEF DESCRIPTION OF THE DRAWINGS

FIG. 1 is a graph of I-V curves of a conventional SONOS memory unit respectively at initial time and after ten thousand cycles.

FIG. 2A is a cross-section view of a memory unit structure according to a first embodiment of the invention during a two-bit programming operation.

FIG. 2B is a cross-section view of the memory unit structure shown in FIG. 2A during a two-bit erasing operation.

FIG. 2C is a cross-section view of the memory unit structure shown in FIG. 2A during a unitary bit programming operation.

FIG. 2D is a cross-section view of the memory unit structure shown in FIG. 2A during a unitary bit erasing operation.

FIG. 3A is a graph of I-V curves of the memory unit structure shown in FIG. 2A respectively at initial time, after fifteen thousand cycles and thirty thousand cycles during a two-bit programming operation.

FIG. 3B is a graph of I-V curves of the memory unit structure shown in FIG. 2A at initial time, after fifteen thousand cycles and thirty thousand cycles during a two-bit erasing operation.

FIG. 4A is a cross-section view of a memory unit structure according to a second embodiment of the invention during a two-bit programming operation.

FIG. 4B is a cross-section view of the memory unit structure shown in FIG. 4A during a two-bit erasing operation.

FIG. 4C is a cross-section view of the memory unit structure shown in FIG. 4A during a unitary bit programming operation.

FIG. 4D is a cross-section view of the memory unit structure shown in FIG. 4A during a unitary bit erasing operation.

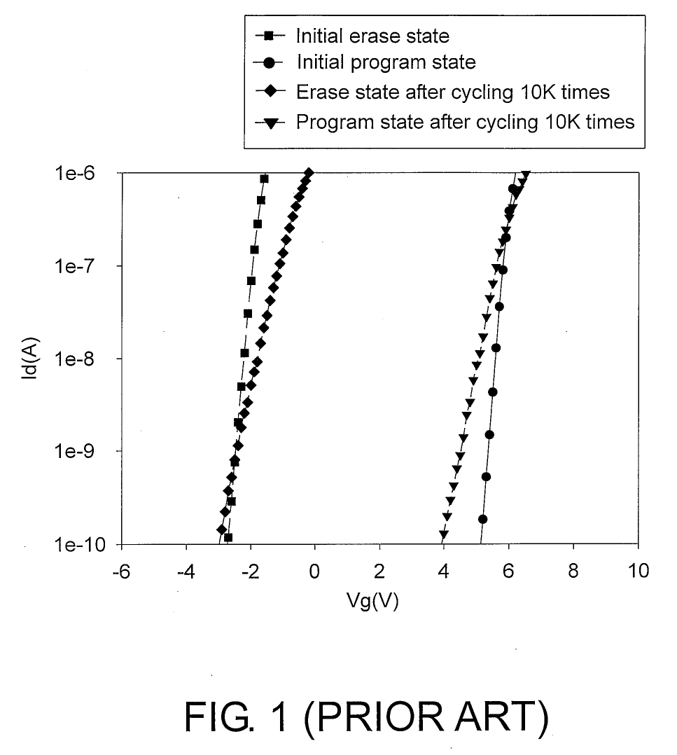

### DESCRIPTION OF THE EMBODIMENTS

Embodiments of the invention will be described in detail with reference to accompanying drawings. However, the invention can be practiced by various means, and is not intended to limit to the embodiments described in the specification. Moreover, for purpose of clarity, the layers and regions may be exaggerated and are not illustrated in scale.

In addition, the terms used in the specification are intended to describe the following embodiments, rather than to limit the invention. As far as the terms, such as “first”, “second”, are only used to distinguish one area, layer or part from another area, layer or part, and not intended to indicate the order of formation or operation.

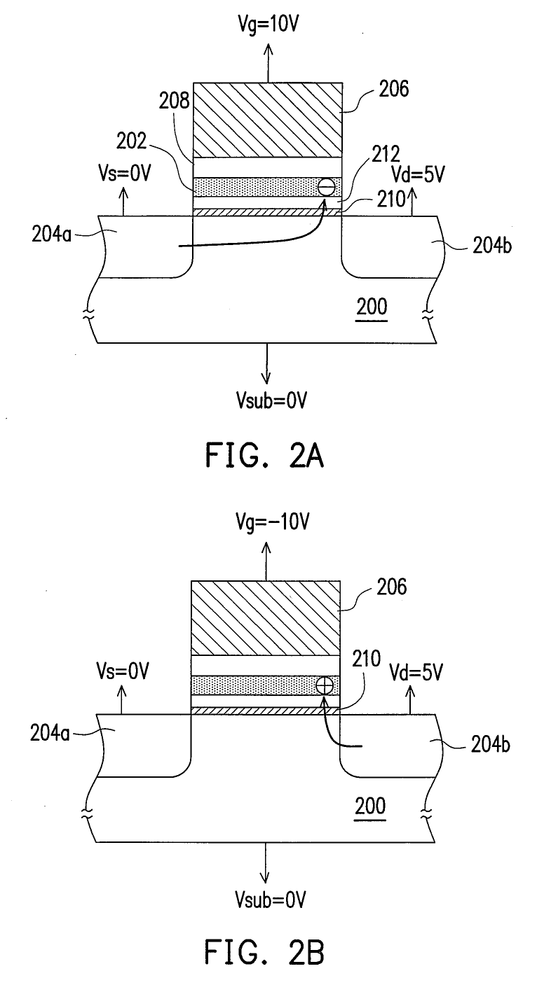

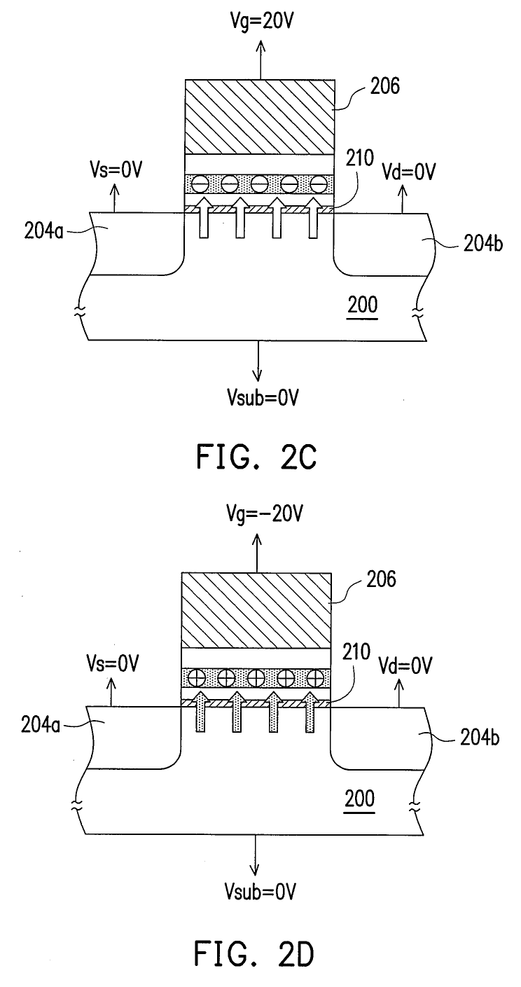

FIG. 2A is a cross-section view of a memory unit structure according to a first embodiment of the invention during a two-bit programming operation.

Referring to FIG. 2A, the memory unit of the first embodiment includes a Si substrate 200, a trapping layer 202, a first doping region 204a and a second doping region 204b, a gate 206, a first oxide layer 208, a high-Dit material layer 210 and a second oxide layer 212. In this embodiment, the Si substrate 200 is a p-type Si substrate, and the first doping region 204a and the second doping region 204b are n-type doping regions. The trapping layer 202 is on the Si substrate 200, and the first and the second doping regions 204a and 204b are formed in the Si substrate 200 on either side of the trapping layer 202, respectively. The gate 206 is formed on the trapping layer 202, and the first oxide layer 208 is formed between the gate 206 and the trapping layer 202. The high-Dit material layer 210 is formed between the Si substrate 200 and the trapping layer 202, and the second oxide layer 212 is formed between the high-Dit material layer 210 and the trapping layer 202, wherein an interface trap density (Dit) between the high-Dit material layer 210 and the Si substrate 200 is in a range of 10¹¹ cm⁻²eV⁻¹ to 10¹³ cm⁻²eV⁻¹, preferably 10¹² cm⁻²eV⁻¹. Additionally, a thickness of the high-Dit material layer 210 is, for example, in a range of 10 Å to 70 Å, preferably 30 Å. The material of the high-Dit material layer 210b can be silicon nitride, or, be one of hafnium dioxide (HfO₂), zirconium dioxide (ZrO₂), zirconium oxynitride (ZrOₓN_{y}), hafnium oxynitride (HfOₓN_{y}), hafnium silicate (HfSiₓO_{y}), zirconium silicate (ZrSiₓO_{y}), hafnium silicon oxynitride (HfSiₓO_{y}N_{z}), alumina (Al₂O₃), titanium dioxide (TiO₂), tantalic oxide (Ta₂O₅), lanthanum sesquioxide (La₂O₃), cerium dioxide (CeO₂), bismuth silicate (Bi₄Si₂O₁₂), wolframium oxide (WO₃), yttrium oxide (Y₂O₃), lanthanum aluminate (LaAlO₃), barium strontium titanate (Ba₁₋ₓSrₓTiO₃), barium titanate (BaTiO₃), lead zirconate (PbZrO₃), lead scandium tantalate (PbSc_{z}Ta_{1-z}O₃, PST for short), lead zinc niobate (PbZn_{z}Nb_{1-z}O₃, PZN for short), lead zirconate titanate (PbZrO₃—PbTiO₃, PZT for short), and lead magnesium niobate (PbMg_{z}Nb_{1-z}O₃, PMN for short).

Please refer to FIG. 2A, when the memory unit of this embodiment is undergone an operation of two-bit programming, as shown in FIG. 2A, a first positive voltage (e.g., Vg=10 Volt) is applied to the gate 206, a second positive voltage (e.g., Vd=5 Volt) is applied to the second doping region 204b which can be used as a drain, and the voltage of the first doping region 204a which can be used as a source is set at 0 Volt (Vs=0 Volt), so as to program bits on one side of the memory unit (i.e., bits on the drain side) by means of channel hot electron (CHE). And the Si substrate 200 is generally grounded, so its voltage V_{sub} is 0 Volt. On the other hand, the first doping region 204a can also be used as a drain, and the second doping region 204b can be used as a source. In other words, when the first positive voltage is applied to the gate, the second positive voltage is applied to the source, and the voltage of the drain is set at 0 Volt, the bits on the source side of the memory unit can be programmed. Furthermore, the first positive voltage is higher than the second positive voltage.

FIG. 2B is a cross-section view of the memory unit structure shown in FIG. 2A during a two-bit erasing operation.

Referring to FIG. 2B, when the memory unit of this embodiment is undergone a two-bit erasing operation, a first negative voltage (e.g., Vg=−10 Volt) is required to apply to the gate 206, to apply a third positive voltage (e.g., Vd=5 Volt) to the second doping region 204b, and to set the voltage of the first doping region 204a at 0 Volt (e.g., Vs=0 Volt), so as to erase bits on one side of the memory unit (i.e., the bits on the drain side) by means of band-to-band tunneling hot hole (BTBTHH).

In addition to the two-bit operation, a unitary bit operation can also be performed on the memory unit structure of the first embodiment, as shown in FIGS. 2C and 2D.

FIG. 2C is a cross-section view of the memory unit structure shown in FIG. 2A during a unitary bit programming operation. Referring to FIG. 2C, when the memory unit is undergone the unitary bit programming operation, it is required to apply a fourth positive voltage (e.g., Vg=20 Volt) to the gate 206, and to set the voltages of the first doping region 204a and the second doping region 204b at 0 Volt (Vs=0 Volt, Vd=0 Volt), so as to program the memory unit by means of Fowler-Nordheim (FN).

FIG. 2D is a cross-section view of the memory unit structure shown in FIG. 2A during a unitary bit erasing operation. Please refer to FIG. 2D, when the memory unit is undergone the unitary bit erasing operation, it is required to apply a second negative voltage (e.g., Vg=−20 Volt) to the gate 204, and to set the first doping region 204a and the second doping region 204b at 0 Volt (Vs=0 Volt, Vd=0 Volt), so as to erase the memory unit by means of Fowler-Nordheim (FN).

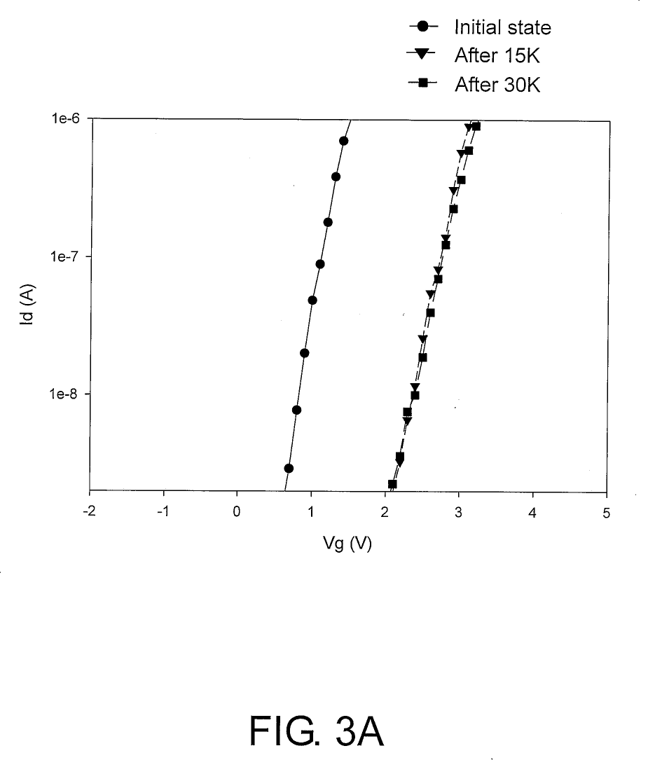

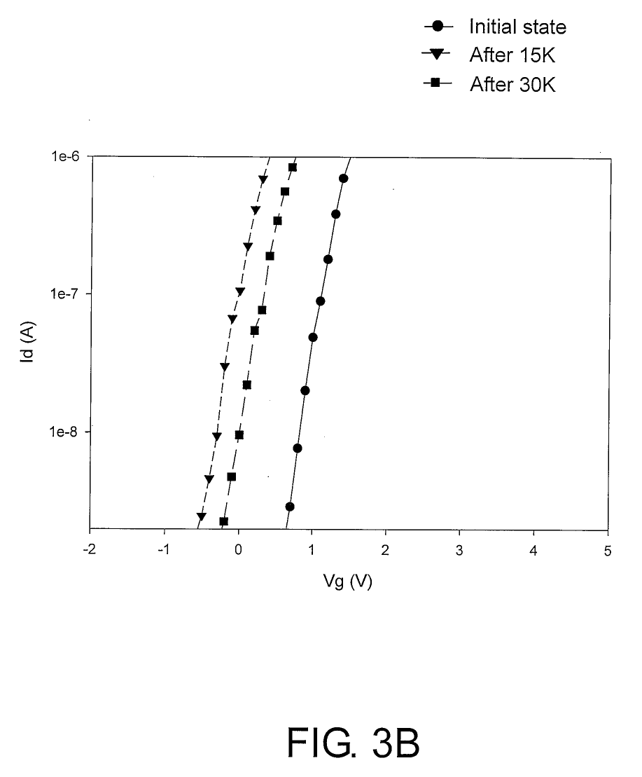

Please refer to FIGS. 3A and 3B, which prove the memory unit of first embodiment can maintain stable swing performance after a number of cycles.

FIG. 3A is a graph of I-V curve of the memory unit structure shown in FIG. 2A at initial time, after fifteen thousand cycles and thirty thousand cycles during the two-bit programming operation, and FIG. 3B is a graph of I-V curve of the memory unit structure shown in FIG. 2B at initial time, after fifteen thousand cycles and thirty thousand cycles during the two-bit erasing operation. As known in FIGS. 3A and 3B, a slop of either the initial program state in FIG. 3A or the initial erase state in FIG. 3B is substantially same as those after 15K and 30K cycles. In other words, the memory unit of the first embodiment can still maintain stable swing performance after a number of operation cycles.

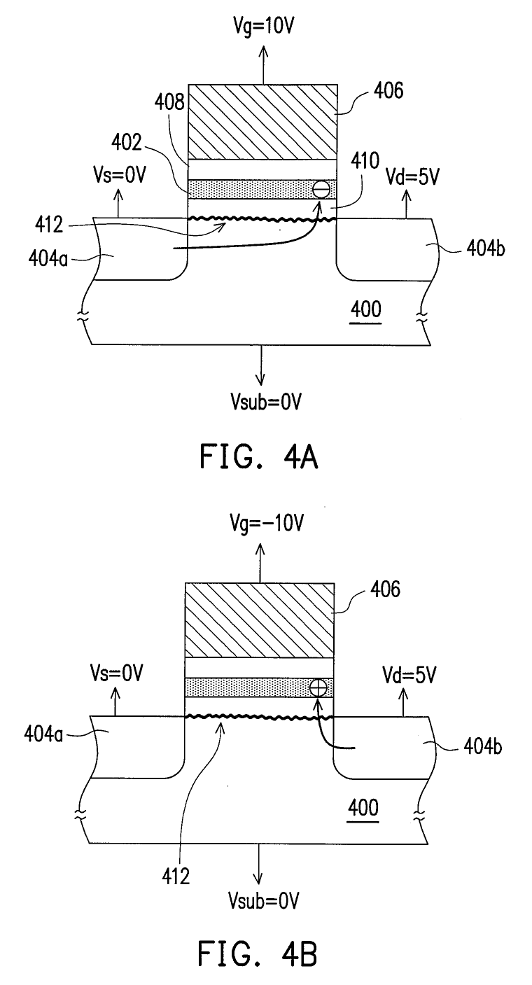

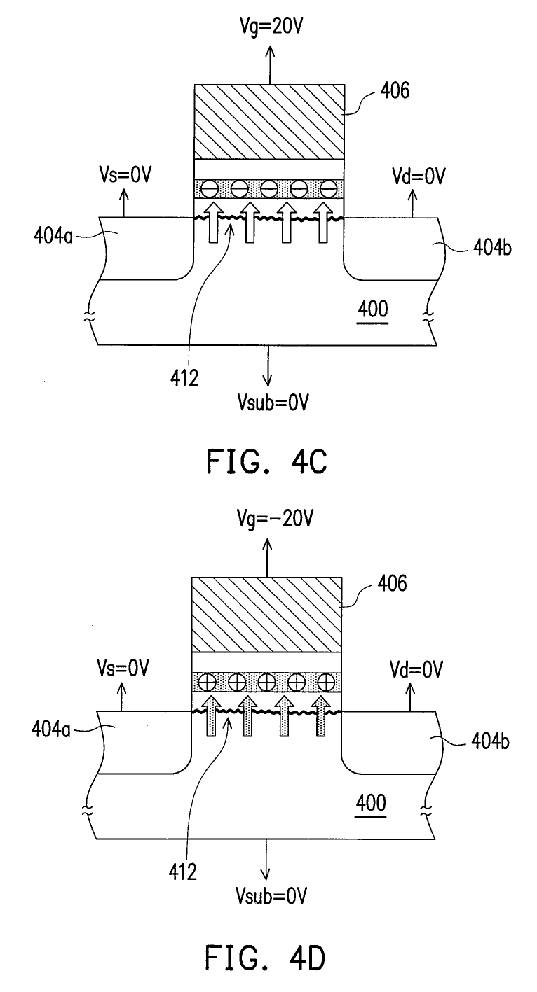

FIG. 4A is a cross-section view of a memory unit structure according to a second embodiment of the invention during a two-bit programming operation.

Referring to FIG. 4A, the memory unit of the second embodiment includes a Si substrate 400, a trapping layer 402, a first doping region 404a and a second doping region 404b; a gate 406, a first dielectric layer 408 and a second dielectric layer 410. In this embodiment, the Si substrate 400 is a p-type Si substrate, the first and the second doping regions 404a, 404b are n-type doping regions, wherein the first dielectric layer 408 is an oxide layer, for example. There is an interface 412 having high interface trap (HIT) property between the second dielectric layer 410 and the Si substrate 400, the interface trap density (Dit) of which is in the range of 10¹¹ cm⁻²eV⁻¹ to 10¹³ cm⁻²eV⁻¹, preferably 10¹² cm⁻²eV⁻¹. Furthermore, the second dielectric layer 410 can be an oxide layer. For example, a worst thermal oxidation process or an implantation method after the thermal oxidation may be selectively used to set the Dit of the interface 412 in the range of 10¹¹ cm⁻²eV⁻¹ to 10¹³ cm⁻²eV⁻¹. In this embodiment, for example, the Si substrate 400 mentioned above can be a p-type Si substrate, and the first and the second doping regions 404a, 404b can be n-type doping regions.

Referring to FIG. 4A, when the memory unit of this embodiment is undergone the two-bit programming operation, a first positive voltage (e.g., Vg=10 Volt) is applied to the gate 406, a second positive voltage (e.g., Vd=5 Volt) is applied to the second doping region 404b which can be used as a drain, the voltage of the first doping region 404a which can be used as a source is set at 0 Volt (Vs=0 Volt), so as to program bits on one side of the memory unit (i.e., the bits on the drain side) by means of channel hot electron (CHE), and generally the voltage V_{sub} is at 0 Volt. Additionally, the first and the second doping regions 104a, 104b can be changed as a drain and a source respectively, not limited to the second embodiment. In other words, when the first positive voltage is applied to the gate, the second positive voltage is applied to the source, and the voltage of the drain is at 0 Volt, bits on the source side of the memory unit can be programmed. The first positive voltage is generally higher than the second positive voltage.

FIG. 4B is a cross-section view of the memory unit structure shown in FIG. 4A during a two-bit erasing operation.

Referring to FIG. 4B, when the memory unit of this embodiment is undergone the two-bit erasing operation, a first negative voltage (e.g., Vg=−10 Volt) is applied to the gate 406, a third positive voltage (e.g., Vd=5 Volt) is applied to the second doping region 404b, and the voltage of the first doping region 404a is set at 0 Volt (e.g., Vs=0 Volt), so as to erase bits on one side of the memory unit (i.e., the bits on the drain side) by means of band-to-band tunneling hot hole (BTBTHH).

With respect to the memory unit structure of the second embodiment, an programming or an erasing can also be performed by a unitary bit operation, as shown in FIGS. 4C and 4D, which are cross-section views of the memory unit structure shown in FIG. 4A during unitary bit programming and erasing operations, respectively.

Referring to FIG. 4C, a fourth positive voltage (e.g., Vg=20 Volt) is applied to the gate 406, and the voltages of the first doping region 404a and the second doping region 404b are set at 0 Volt (Vs=0 Volt, Vd=0 Volt), so as to program the memory unit by means of Fowler-Nordheim (FN).

Referring to FIG. 4D, a second negative voltage (e.g., Vg=−20 Volt) is applied to the gate 404 and the voltages of the first doping region 404a and the second doping region 404b are set at 0 Volt (Vs=0 Volt, Vd=0 Volt), so as to erase the memory unit by means of Fowler-Nordheim (FN).

As mentioned above, because the interface between the Si substrate and the upper layer thereof has a high interface trap density (Dit) of 10¹¹ cm⁻²eV⁻¹˜10¹³ cm⁻²eV⁻¹, the change in Dit value is not significant, when a number of memory unit operations is increasing. Therefore, the swing performance of the memory unit cannot be significantly degraded. The operation, cycle endurance, and data retention of the memory unit can be improved after the number of cycles gradually increases.

While the invention have been described with reference to preferred embodiments, It will be apparent to those skilled in the art that various modifications and variations can be made to the present invention without departing from the scope or spirit of the invention. Therefore, it is intended that the scope of the present invention is defined by appended claims and their equivalents.

What is claimed is:

1. A memory unit structure, comprising:
a Si substrate;
a trapping layer formed on the Si substrate;
a first doping region and a second doping region formed in the Si substrate on either side of the trapping layer, respectively;
a gate formed on the trapping layer;
a first oxide layer formed between the gate and the trapping layer;
a high-Dit material layer formed between the Si substrate and the trapping layer; and
a second oxide layer formed between the high-Dit material layer and the trapping layer,
wherein an interface trap density between the high-Dit material layer and the Si substrate is in a range of 10¹¹ cm⁻²eV⁻¹ to 10¹³ cm⁻²eV⁻¹.

2. The memory unit structure according to claim 1, wherein the interface trap density between the high-Dit material layer and the Si substrate is 10¹² cm⁻²eV⁻¹.

3. The memory unit structure according to claim 1, wherein a thickness of the high-Dit material layer is in a range of 10 Å to 70 Å.

4. The memory unit structure according to claim 1, wherein the material of the high-Dit material layer comprises silicon nitride.

5. The memory unit structure according to claim 1, wherein the material of the high-Dit material layer comprises hafnium dioxide (HfO₂), zirconium dioxide (ZrO₂), zirconium oxynitride (ZrOₓN_{y}), hafnium oxynitride (HfOₓN_{y}), hafnium silicate (HfSiₓO_{y}), zirconium silicate (ZrSiₓO_{y}), hafnium silicon oxynitride (HfSiₓO_{y}N_{z}), alumina (Al₂O₃), titanium dioxide (TiO₂), tantalic oxide (Ta₂O₅), lanthanum sesquioxide (La₂O₃), cerium dioxide (CeO₂), bismuth silicate (Bi₄Si₂O₁₂), wolframium oxide (WO₃), yttrium oxide (Y₂O₃), lanthanum aluminate (LaAlO₃), barium strontium titanate (Ba₁₋ₓSrₓTiO₃), barium titanate (BaTiO₃), lead zirconate (PbZrO₃), lead scandium tantalate (PbSc_{z}Ta_{1-z}O₃, PST for short), lead zinc niobate (PbZn_{z}Nb_{1-z}O₃, PZN for short), lead zirconate titanate (PbZrO₃—PbTiO₃, PZT for short), or lead magnesium niobate (PbMg_{z}Nb_{1-z}O₃, PMN for short).

6. The memory unit structure according to claim 1, wherein the Si substrate is a p-type Si substrate, and the first doping region and the second doping region are n-type doping regions.

7. A memory unit operation method adapted to a memory unit comprising a Si substrate; a trapping layer formed on the Si substrate; a first doping region and a second doping region formed in the Si substrate on either side of the trapping layer, respectively; a gate formed on the trapping layer; a first oxide layer formed between the gate and the trapping layer; a high-Dit material layer formed between the Si substrate and the trapping layer; and a second oxide layer formed between the high-Dit material layer and the trapping layer, wherein an interface trap density (Dit) between the high-Dit material layer and the Si substrate is in a range of 10¹¹ to 10¹³ cm⁻²eV⁻¹, the operation method comprising:
when the memory unit is programmed, applying a first positive voltage to the gate, applying a second positive voltage to the second doping region, and setting the voltage of the first doping region at 0 Volt, so as to program bits on one side of the memory unit by means of channel hot electron; and
when the memory unit is erased, applying a first negative voltage to the gate, applying a third positive voltage to the second doping region, and setting the voltage of the first doping region at 0 Volt, so as to erase the bits on the side of the memory unit by means of band-to-band tunneling hot hole.

8. The memory unit operation method according to claim 7, wherein the first doping region is a source and the second doping region is a drain.

9. The memory unit operation method according to claim 7, wherein the first doping region is a drain, and the second doping region is a source.

10. The memory unit operation method according to claim 7, wherein the first positive voltage is higher than the second positive voltage.

11. A memory unit operation method adapted to a memory unit comprising a Si substrate; a trapping layer formed on the Si substrate; a first doping region and a second doping region formed in the Si substrate on either side of the trapping layer, respectively; a gate formed on the trapping layer; a first oxide layer formed between the gate and the trapping layer; a high-Dit material layer formed between the Si substrate and the trapping layer; and a second oxide layer formed between the high-Dit material layer and the trapping layer, wherein an interface trap density (Dit) between the high-Dit material layer and the Si substrate is in a range of 10¹¹ cm⁻²eV⁻¹ to 10¹³ cm⁻²eV⁻¹, the operation method comprising:
when the memory unit is programmed, applying a fourth positive voltage to the gate, and setting the voltages of the first doping region and the second doping region at 0 Volt, so as to program the memory unit by means of Fowler-Nordheim; and
when the memory unit is erased, applying a second negative voltage to the gate, and setting the voltages of the first doping region and the second doping region at 0 Volt, so as to erase the memory unit by means of Fowler-Nordheim.

12. The memory unit operation method according to claim 11, wherein the first doping region is a source, and the second doping region is a drain.

13. The memory unit operation method according to claim 11, wherein the first doping region is a drain, and the second doping region is a source.

14. A memory unit structure, comprising:
a Si substrate;
a trapping layer formed on the Si substrate;
a first doping region and a second doping region formed in the Si substrate on either side of the trapping layer, respectively;
a gate formed on the trapping layer;
a first dielectric layer formed between the gate and the trapping layer; and
a second dielectric layer formed between the Si substrate and the trapping layer, wherein an interface trap density (Dit) between the second dielectric layer and the Si substrate is in a range of 10¹¹ cm⁻²eV⁻¹ to 10¹³ cm⁻²eV⁻¹.

15. The memory unit structure according to claim 14, wherein the interface trap density between the second dielectric layer and the Si substrate is 10¹² cm⁻²eV⁻¹.

16. The memory unit structure according to claim 14, wherein the second dielectric layer comprises an oxide layer.

17. The memory unit structure according to claim 14, wherein the Si substrate is a p-type Si substrate, and the first doping region and the second doping region are n-type doping regions.

18. The memory unit structure according to claim 14, wherein the first dielectric layer comprises an oxide layer.

19. A memory unit operation method adapted to a memory unit comprising a Si substrate; a trapping layer formed on the Si substrate; a first doping region and a second doping region formed in the Si substrate on either side of the trapping layer, respectively; a gate formed on the trapping layer; a first dielectric layer formed between the gate and the trapping layer; and a second dielectric layer formed between the Si substrate and the trapping layer, wherein an interface trap density (Dit) between the second dielectric layer and the Si substrate is in a range of 10¹¹ cm⁻²eV⁻¹ to 10¹³ cm⁻²eV⁻¹, the operation method comprising:
when the memory unit is programmed, applying a first positive voltage to the gate, applying a second positive voltage to the second doping region, and setting the voltage of the first doping region at 0 Volt, so as to program bits on one side of the memory unit by means of channel hot electron; and
when the memory unit is erased, applying a first negative voltage to the gate, applying a third positive voltage to the second doping region, and setting the voltage of the first doping region at 0 Volt, so as to erase the bits on the side of the memory unit by means of band-to-band tunneling hot hole.

20. The memory unit operation method according to claim 19, wherein the first doping region is a source, and the second doping region is a drain.

21. The memory unit operation method according to claim 19, wherein the first doping region is a drain, and the second doping region is a source.

22. The memory unit operation method according to claim 19, wherein the first positive voltage is higher than the second positive voltage.

23. A memory unit operation method adapted to a memory unit comprising a Si substrate; a trapping layer formed on the Si substrate; a first doping region and a second doping region formed in the Si substrate on either side of the trapping layer, respectively; a gate formed on the trapping layer; a first dielectric layer formed between the gate and the trapping layer; and a second dielectric layer formed between the Si substrate and the trapping layer, wherein an interface trap density (Dit) between the second dielectric layer and the Si substrate is in a range of 10¹¹ to 10¹³ cm⁻²eV⁻¹, the operation method comprising:
when the memory unit is programmed, applying a fourth positive voltage to the gate, and setting the voltages of the first doping region and the second doping region at 0 Volt, so as to program the memory unit by means of Fowler-Nordheim; and
when the memory unit is erased, applying a second negative voltage to the gate, and setting the voltages of the first doping region and the second doping region at 0 Volt, so as to erase the memory unit by means of Fowler-Nordheim.

24. The memory unit operation method according to claim 23, wherein the first doping region is a source, and the second doping region is a drain.

25. The memory unit operation method according to claim 23, wherein the first doping region is a drain, and the second doping region is a source.
